(19) United States
(12) Patent Application Publication
(10) Pub. No.: US 2021/0357052 A1
(43) Pub. Date: Nov. 18, 2021

(54) TOUCH SCREEN AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Jian YE, Wuhan, Hubei (CN)

(21) Appl. No.: 16/615,219

(22) PCT Filed: Jan. 11, 2019
(86) PCT No.: PCT/CN2019/071366

§ 371 Date: Nov. 20, 2019

(30) Foreign Application Priority Data
Dec. 12, 2018 (CN) 201811519536.9

(51) Int. Cl. G06F 3/041; H01L 27/32; H01L 51/00; H01L 51/52

(52) U.S. Cl. CPC G06F 3/0412; H01L 27/323; H01L 27/3246; H01L 2251/5338; H01L 51/0097; H01L 51/5281; G06F 2203/04102; H01L 27/3276

(57) ABSTRACT

A touch screen and a display device are provided. The touch screen includes a substrate, source and drain layers, a planarization layer, an anode layer, a pixel defining layer, and a touch electrode layer stacked in sequence. The touch screen further includes via holes, and the via hole includes a first via hole and a second via hole. The first via hole is defined on the planarization layer, the anode layer is electrically connected to the source and drain layer through the first via hole. The second via hole is defined on the pixel defining layer, and the touch electrode layer is connected to the anode layer through the second via hole.

### FIELD OF INVENTION

The present disclosure relates to a field of display technologies, and more particular, to a touch screen and a display device.

### BACKGROUND OF INVENTION

Current mainstream touch technologies include monolithic glass touch technology and in-cell touch technology. Touch screens are manufactured on display screens by the in-cell touch technology.

The in-cell touch integrates a sensing circuit substrate with a display panel and is divided into on-cell technology and in-cell technology depending on different positions of the sensing circuit. Among those technology, the on-cell technology is widely used in organic light-emitting diode (OLED) display devices.

In an OLED display device employing the on-cell technology, a touch electrode is disposed on a thin film encapsulation layer, one end of a metal wiring is connected to a touch electrode, and the other end of the metal wiring is connected to an array substrate. Because an organic light-emitting layer, a thin film encapsulation layer, etc. are further disposed between the touch electrode and the array substrate, the metal wiring must extend along a direction of the height of those structures. Therefore, the metal wiring is prone to breakage.

### Technical Problem

An object of the present disclosure to provide a touch panel and a display device which can increase durability of bending of the touch screen and the display device.

### SUMMARY OF INVENTION

An embodiment of the present disclosure provides a touch screen comprising a substrate, a source and drain layer, a planarization layer, an anode layer, a pixel defining layer, a touch electrode layer, and via holes;

wherein the source and drain layer is disposed on the substrate;

the planarization layer is disposed on the source and drain layer;

the anode layer is disposed on the planarization layer;

the pixel defining layer is disposed on the anode layer;

the touch electrode layer is disposed on the pixel defining layer;

the via holes comprise a first via hole and a second via hole, the first via hole is defined on the planarization layer, the anode layer is electrically connected to the source and drain layer through the first via hole, the second via hole is defined on the pixel defining layer, and the touch electrode layer is connected to the anode layer through the second via hole.

In some embodiments, the touch screen further comprises a polarizer and a bending section, the polarizer is disposed on the touch electrode layer, and a center position of a bending radius of the bending section is located inside a boundary of the polarizer.

In some embodiments, the bending radius of the bending section ranges from 0.1 to 0.5 millimeters.

In some embodiments, the touch screen comprises a flexible circuit board, the source and drain layer is patterned to form source and drain wirings, the source and drain wirings are connected to a bonding section of the flexible circuit board via the bending section, and the source and drain wirings located at the bending section are curved.

The source and drain wirings located at the bending section comprise a plurality of sub-connecting lines, and the sub-connecting lines are curved.

In some embodiments, the touch electrode layer comprises a plurality of touch sensing lines and driving sensing lines that are intersected with each other, and the touch sensing lines and the driving sensing lines are curved.

In some embodiments, the source and drain wirings located at the bending section include at least two protrusions.

In some embodiments, the source and drain wirings in the bending section comprise at least two protrusions.

In some embodiments, the source and drain wirings located at the bending section further comprise at least one recess, and the recesses and the protrusions are disposed adjacent to each other.

In some embodiments, longitudinal planes of the protrusions are polygons, waist circles, or rectangles, and a longitudinal plane of the recess is rectangle.

In some embodiments, the source and drain wirings in the bending section comprise at least two hollow portions.

The embodiment of the present disclosure further provides a display device, including a touch screen, the touch screen comprising a substrate, a source and drain layer, a planarization layer, an anode layer, a pixel defining layer, a touch electrode layer, and via holes;

wherein the source and drain layer is disposed on the substrate;

the planarization layer is disposed on the source and drain layer;

the anode layer is disposed on the planarization layer;

the pixel defining layer is disposed on the anode layer;

the touch electrode layer is disposed on the pixel defining layer;

the via holes comprise a first via hole and a second via hole, the first via hole is defined on the planarization layer, the anode layer is electrically connected to the source and drain layer through the first via hole, the second via hole is defined on the pixel defining layer, and the touch electrode layer is connected to the anode layer through the second via hole.

In some embodiments, the touch screen further comprises a polarizer and a bending section, the polarizer is disposed on the touch electrode layer, and a center position of a bending radius of the bending section is located inside a boundary of the polarizer.

In some embodiments, the bending radius of the bending section ranges from 0.1 to 0.5 millimeters.

In some embodiments, the touch screen comprises a flexible circuit board, the source and drain layer is patterned to form source and drain wirings, the source and drain wirings are connected to a bonding section of the flexible circuit board via the bending section, and the source and drain wirings located at the bending section are curved.

The source and drain wirings located at the bending section comprise a plurality of sub-connecting lines, and the sub-connecting lines are curved.

In some embodiments, the touch electrode layer comprises a plurality of touch sensing lines and driving sensing lines that are intersected with each other, and the touch sensing lines and the driving sensing lines are curved.

In some embodiments, the source and drain wirings in the bending section comprise at least two protrusions.

In some embodiments, the source and drain wirings located at the bending section further comprise at least one recess, and the recesses and the protrusions are disposed adjacent to each other.

In some embodiments, longitudinal planes of the protrusions are polygons, waist circles, or rectangles, and a longitudinal plane of the recess is rectangle.

In some embodiments, the source and drain wirings in the bending section comprise at least two hollow portions.

### Beneficial Effects

Compared with the conventional touch screen and display device, by electrically connecting the source and drain layer to the anode layer and electrically connecting the anode layer to the touch electrode layer, the touch screen and the display device of the present disclosure not only achieve the electrical connection between the layer and the touch electrode layer, but also increase durability of bending of the touch screen.

### DESCRIPTION OF DRAWINGS

For a better understanding of the aforementioned content of the present invention, preferable embodiments are illustrated in accordance with the attached figures for detailed explanation.

FIG. 1 is a structural schematic diagram of a touch screen according to an embodiment of the present disclosure;

FIG. 2 is a structural schematic diagram of source and drain wirings according to an embodiment of the present disclosure;

FIG. 3 is a structural schematic diagram of a bending touch screen according to an embodiment of the present disclosure; and

FIG. 4 is another structural schematic diagram of the source and drain wirings according to an embodiment of the present disclosure.

### DETAILED DESCRIPTION OF PREFERRED EMBODIMENTS

In the following detailed description, reference is made to the accompanying figures, in which various examples are shown by way of illustration. In this regard, directional terminology mentioned in the present disclosure, such as “top”, “bottom”, “front”, “back”, “left”, “right”, “inner”, “outer”, “lateral”, etc., is used with reference to the orientation of the figures being described. Therefore, the directional terminology is used for purposes of illustration and is not intended to limit the present invention.

In the accompanying figures, units with similar structures are indicated by the same reference numbers.

The term “embodiment” referred to herein means that a particular feature, structure, or property described in conjunction with the implementation may be contained in at least one implementation of the present disclosure. The phrase appearing in various places in the specification does not necessarily refer to the same implementation, nor does it refer to an independent or alternative implementation that is mutually exclusive with other implementations. As one of ordinary skill in the art explicitly and implicitly appreciate, the implementations described herein may be combined with other implementations.

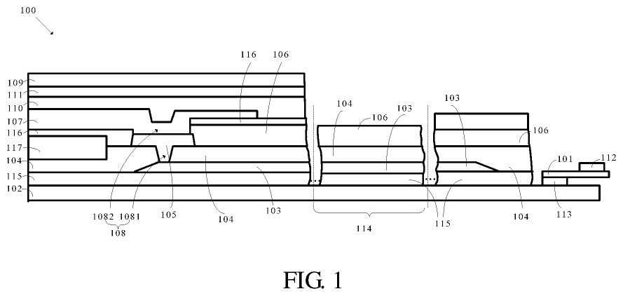

An embodiment of the present disclosure provides a display device including a touch screen. Please refer to FIG. 1. FIG. 1 is a structural schematic diagram of a touch screen according to an embodiment of the present disclosure. The touch screen 100 includes a flexible circuit board 101, a substrate 102, a source and drain layer 103, a planarization layer 104, an anode layer 105, a pixel defining layer 106, a touch electrode layer 107, and a via hole 108.

The substrate 102 includes structures, such as a thin film transistor, a substrate, etc., for carrying structures of the flexible circuit board 101, the source and drain layer 103, and the planarization layer 104. The substrate may be a flexible substrate made of a flexible material, such as polyimide, polycarbonate, polyether sulfone, polyethylene terephthalate, polyethylene naphthalate, polyarylate, etc.

The flexible circuit board 101 is disposed on the substrate 102. The flexible circuit board 101 includes a bonding section and a non-bonding section. The bonding section of the flexible circuit board 10 is used for fixing with the substrate 102. Specifically, a glue layer 113 may be disposed between the bonding section of the flexible circuit board 101 and the substrate 102 to fix the flexible circuit board 101 and the substrate 102 together. The glue layer 113 includes a substrate and conductive particles. The substrate may be a thermosetting resin, and the conductive particles are encapsulated in the substrate. After the glue layer 113 is heat pressed, the conductive particles are released. The conductive particles are electrically connected to the conductive substrate of the substrate 102 and the pin terminals of the flexible circuit board 101 so that the flexible circuit board 101 is electrically connected to the substrate 102. As shown in FIG. 1, the flexible circuit board 101 is further provided with a driving chip 112 for controlling the touch screen 100 to quickly and accurately display a picture.

The source and drain layer 103 is disposed on the substrate 102. The source and drain layer 103 may be made of titanium/aluminum/titanium (Ti/Al/Ti). The source and drain layer 103 is patterned to form source and drain wirings 1031. As shown in FIG. 1, a non-display area of the touch screen 100 also has a bending section 114 for bending the touch screen 100. The source and drain wirings 1031 are connected to the bonding section of the flexible circuit board 101 via the bending section 114. The source and drain wirings 1031 located on the bending section 114 may be curved to increase a stressed area thereof and durability of bending of the touch screen 100.

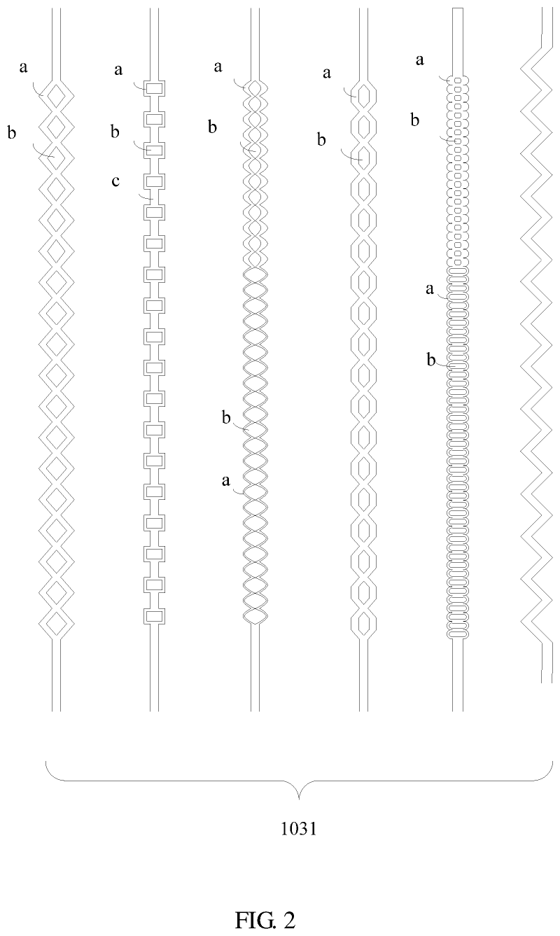

As shown in FIG. 2, the source and drain wirings 1031 located on the bending section 114 include at least two protrusions a, which are serially connected. Longitudinal planes of the protrusions a may have shapes such as polygons, round waist shapes, or rectangles, or a combination of two or more of the above shapes. Specifically, the polygons may be axisymmetric polygons or irregular polygons.

The source and drain wirings 1031 located on the bending section 114 include at least two hollow portions b. The protrusions a are disposed around the hollow portions b. Preferably, the hollow portions b are disposed as a center of the protrusions a. The adjacent hollow portions b may be disposed adjacent to each other or may be spaced apart from each other. Longitudinal planes of the hollow portions b may have shapes matching the longitudinal planes of the protrusions a. For example, when the longitudinal planes of the protrusions a are hexagonal, the longitudinal planes of the hollow portions b are quadrangle. When the longitudinal planes of the protrusions a are round waist shapes, the longitudinal planes of the hollow portions b are ovals. By providing the hollow portions b, the stress received by the source and drain wirings 1031 located on the bending section 114 can be reduced when the touch screen 100 is bent and the durability of bending of the source and drain wirings 1031 located on the bending section 114 can be increased.

In some embodiments, the source and drain wirings 1031 located on the bending section 114 further include at least a recess c that is defined adjacent to the recess a. A longitudinal plane of the recess c may be rectangular. The recess c may also be provided with a hollow structure to further increase the durability of bending of the source and drain wirings 1031. A longitudinal plane of the hollow structure may have a shape such as a rectangle or a circle which matches the longitudinal plane of the recess c.

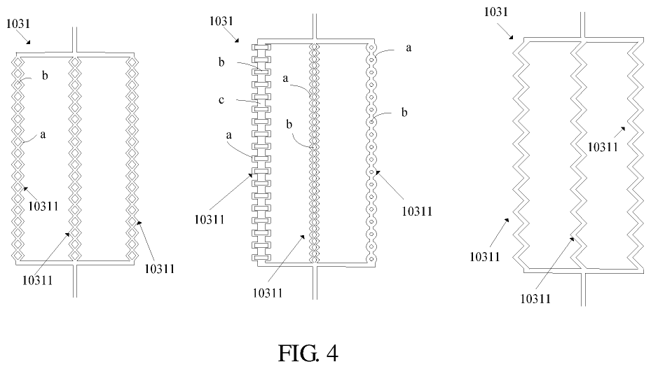

In some embodiments, as shown in FIG. 4, the source and drain wirings 1031 located on the bending section 114 may be disposed to include a plurality of sub-connecting lines 10311, such that if one of the sub-connecting lines 10311 is broken, the other sub-connecting line 10311 can ensure that the source and drain wiring 1031 is in an on state. Preferably, the sub-connecting lines 10311 can also be curved. The specific arrangement is similar to the single source and drain wiring described above, and details are not described herein again. It should be noted that, as shown in FIG. 4, the sub-connecting lines 10311 located at the same source and drain wiring 1031 may have the same or different crooked shapes which are not specifically limited herein.

In some embodiments, a buffer layer 115 is further disposed between the source and drain layer 103 and the substrate 102. The buffer layer 115 can be used to reduce the stress received by the touch screen 100 when the touch screen 100 is bent. Specifically, the buffer layer 115 may be composed of a material such as silicon nitride SiNₓ or silicon oxide SiOₓ.

A planarization layer 104 is disposed over the source and drain layer 103 for providing a planar surface. The anode layer 105 is disposed on the planarization layer 104. The pixel defining layer 106 is disposed on the anode layer 105. The touch electrode layer 107 is disposed on the pixel defining layer 106. The touch electrode layer 107 includes a plurality of touch sensing lines and driving sensing lines that are intersected with each other. Specifically, the touch electrode layer 107 is disposed on a gap region between adjacent pixels. In some embodiments, the touch sensing lines and the driving sensing lines in the touch electrode layer 107 may also be disposed in the same shape as the source and drain wirings 1031 described above.

The touch screen includes a display area and a non-display area. The via holes 108 are located at the non-display area, and includes a first via hole 1081 and a second via hole 1082. The first via hole 1081 is defined on the planarization layer 104, and the anode layer 105 is electrically connected to the source and drain layer 103 through the first via hole 1081. The second via hole 1082 is defined on the pixel defining layer 106. The touch electrode layer 107 is connected to the anode layer 105 through the second via hole 1082. Specifically, after the planarization layer 104 is formed on the source and drain layer 103. First, the first via hole 1081 is formed on the planarization layer 104. Then, the first via hole 1081 is filled with material, such as indium tin oxide (ITO), gold (Au), or indium oxide (IZO). The material covers the planarization layer 104 to form the anode layer 105, so that the anode layer 105 is electrically connected to the source and drain layer 103.

In an embodiment, the touch screen 100 further includes a protective layer 116 and a thin film encapsulation layer 117. The thin film encapsulation layer 117 is located at the non-display area. Specifically, the thin film encapsulation layer 117 is disposed on the planarization layer 104. The thin film encapsulation layer 117 may include two layers of encapsulation film to block the erosion of the touch screen 100 by external moisture and oxygen. The thin film encapsulation layer 117 may be composed of material, such as silicon nitride (SiNₓ), silicon dioxide (SiO₂), etc. The protective layer 116 is disposed on the pixel defining layer 106. Since the pixel defining layer 106 is composed of a photoresist material, the protective layer 116 can prevent the pixel defining layer 106 from being damaged by subsequent etching.

Similarly, the pixel defining layer 106 may be first formed on the anode layer 105, the planarization layer 104, and the thin film encapsulating layer 117. Then, the protective layer 116 is formed on the pixel defining layer 106. Then, the protective layer 116 is formed on the pixel defining layer 106. Next, the second via hole 1082 is formed on the protective layer. Finally, the second via hole 1082 is filled with a metal material and partially covered with the protective layer 116 to form the touch electrode layer 107. The electrical connection between the touch electrode layer 107 and the anode layer 105 can be achieved.

First, the above-mentioned touch electrode layer 107 is electrically connected to the anode layer 105. Then the touch electrode layer 107 is electrically connected to the source and drain layer 103 using the anode layer 105 as a bridge, thereby preventing the situation that the height difference between the touch electrode layer 107 and the source and drain layer 103 is too high that the metal wiring is easily broken, when the touch electrode layer 107 is directly electrically connected to the source and drain layer 103 via the metal wiring. Furthermore, the source and drain layer 103 is electrically connected to the bonding section of the flexible circuit board 101. Therefore, the touch electrode layer 107 can be electrically connected to the bonding section of the flexible circuit board 101.

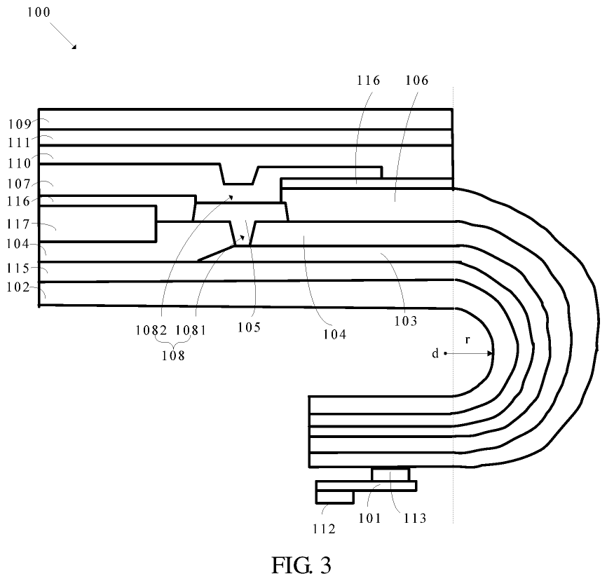

In some embodiments, the touch screen 100 further includes a polarizer 109 disposed on the touch electrode layer 107. As shown in FIG. 1, the touch screen 100 further includes a passivation layer 110 and a glue layer 111. A passivation layer 110 is disposed on the touch electrode layer 107. A glue layer 111 is disposed on the passivation layer 110. A polarizer 109 is disposed on the glue layer 111. An edge of the polarizer 109 is located between the via hole 108 and the bending section 114. As shown in FIG. 3, when the touch screen 100 is bent, a bending radius r of the touch screen 100 is between 0.1 to 0.5 mm. A center position of the touch screen 100 is d, and the center position d is located inside a boundary of the polarizer 109. Therefore, the width of the non-display area of the touch screen 100 can be reduced, i.e., the width of the bezel of the touch screen 100 is reduced and a narrow bezel is achieved.

By electrically connecting the source and drain layer to the anode layer and electrically connecting the anode layer to the touch electrode layer, the touch screen and the display device of the present disclosure not only achieve the electrical connection between the layer and the touch electrode layer, but also increase durability of bending of the touch screen.

In summary, although the present invention has been described with preferred embodiments thereof, the above preferred embodiments is not used to limit the present invention. One of ordinarily skill in the art can carry out changes and modifications to the described embodiment without departing from the scope and the spirit of the invention that is intended to be limited only by the appended claims.

1. A touch screen, comprising a substrate, a source and drain layer, a planarization layer, an anode layer, a pixel defining layer, a touch electrode layer, and via holes;
wherein the source and drain layer is disposed on the substrate;
the planarization layer is disposed on the source and drain layer;
the anode layer is disposed on the planarization layer;
the pixel defining layer is disposed on the anode layer;
the touch electrode layer is disposed on the pixel defining layer;
the via holes comprise a first via hole and a second via hole, the first via hole is defined on the planarization layer, and the anode layer is electrically connected to the source and drain layer through the first via hole, the second via hole is defined on the pixel defining layer, and the touch electrode layer is connected to the anode layer through the second via hole.

2. The touch screen according to claim 1, wherein the touch screen further comprises a polarizer and a bending section, the polarizer is disposed on the touch electrode layer, and a center position of a bending radius of the bending section is located inside a boundary of the polarizer.

3. The touch screen according to claim 2, wherein the bending radius of the bending section ranges from 0.1 to 0.5 millimeters.

4. The touch screen according to claim 2, wherein the touch screen comprises a flexible circuit board, the source and drain layer is patterned to form source and drain wirings, and the source and drain wirings are connected to a bonding section of the flexible circuit board via the bending section, and the source and drain wirings located at the bending section are curved.

5. The touch screen according to claim 4, wherein the source and drain wirings located at the bending section comprise a plurality of sub-connecting lines, the sub-connecting lines being curved.

6. The touch screen according to claim 1, wherein the touch electrode layer comprises a plurality of touch sensing lines and driving sensing lines that are intersected with each other, and the touch sensing lines and the driving sensing lines are curved.

7. The touch screen according to claim 4, wherein the source and drain wirings in the bending section comprise at least two protrusions.

8. The touch screen according to claim 7, wherein the source and drain wirings located at the bending section further comprise at least one recess, and the recesses and the protrusions are disposed adjacent to each other.

9. The touch panel according to claim 8, wherein longitudinal planes of the protrusions are polygons, waist circles, or rectangles, and longitudinal planes of the recess are rectangles.

10. The touch screen according to claim 7, wherein the source and drain wirings in the bending section comprise at least two hollow portions.

11. A display device, comprising a touch screen, the touch screen comprising a substrate, a source and drain layer, a planarization layer, an anode layer, a pixel defining layer, a touch electrode layer, and via holes;
wherein the source and drain layer is disposed on the substrate;
the planarization layer is disposed on the source and drain layer;
the anode layer is disposed on the planarization layer;
the pixel defining layer is disposed on the anode layer;
the touch electrode layer is disposed on the pixel defining layer;
the via holes comprise a first via hole and a second via hole, the first via hole is defined on the planarization layer, and the anode layer is electrically connected to the source and drain layer through the first via hole, the second via hole is defined on the pixel defining layer, and the touch electrode layer is connected to the anode layer through the second via hole.

12. The touch screen according to claim 11, wherein the touch screen further comprises a polarizer and a bending section, the polarizer is disposed on the touch electrode layer, and a center position of a bending radius of the bending section is located inside a boundary of the polarizer.

13. The touch screen according to claim 12, wherein the bending radius of the bending section ranges from 0.1 to 0.5 millimeters.

14. The touch screen according to claim 12, wherein the touch screen comprises a flexible circuit board, the source and drain layer is patterned to form source and drain wirings, and the source and drain wirings are connected to a bonding section of the flexible circuit board via the bending section, and the source and drain wirings located at the bending section are curved.

15. The touch screen according to claim 14, wherein the source and drain wirings located at the bending section comprise a plurality of sub-connecting lines, the sub-connecting lines being curved.

16. The touch screen according to claim 11, wherein the touch electrode layer comprises a plurality of touch sensing lines and driving sensing lines that are intersected with each other, and the touch sensing lines and the driving sensing lines are curved.

17. The touch screen according to claim 14, wherein the source and drain wirings in the bending section comprise at least two protrusions.

18. The touch screen according to claim 17, wherein the source and drain wirings located at the bending section further comprise at least one recess, and the recesses and the protrusions are disposed adjacent to each other.

19. The touch panel according to claim 18, wherein longitudinal planes of the protrusions are polygons, waist circles, or rectangles, and longitudinal planes of the recess are rectangles.

20. The touch screen according to claim 17, wherein the source and drain wirings in the bending section comprise at least two hollow portions.
